(19) United States
(12) Patent Application Publication
(10) Pub. No.: US 2023/0221079 A1
(43) Pub. Date: Jul. 13, 2023

(54) HEAT PIPE ARRANGEMENT METHOD FOR HEAT DISSIPATION AND TRANSFER DEVICE

(71) Applicant: BEIJING DEEPCOOL INDUSTRIES CO., LTD., Beijing (CN)

(72) Inventor: Heng LI, Beijing (CN)

(73) Assignee: BEIJING DEEPCOOL INDUSTRIES CO., LTD., Beijing (CN)

(21) Appl. No.: 18/180,178

(22) Filed: Mar. 8, 2023

Related U.S. Application Data
(63) Continuation of application No. PCT/CN2020/116520, filed on Sep. 21, 2020.

(30) Foreign Application Priority Data
Sep. 17, 2020 (CN) 202010982789.0

(51) Int. Cl. F28D 15/02; F28F 1/32

(52) U.S. Cl. CPC F28D 15/0275; F28F 1/325; F28F 2250/08

(57) ABSTRACT

Disclosed is a heat pipe arrangement method for a heat dissipation and transfer device. The heat dissipation and transfer device includes a metal base, a heat dissipation fin, a heat dissipation fan and a plurality of heat pipes. Each heat pipe includes a heat absorption end and a heat dissipation end. The heat dissipation ends of the plurality of heat pipes are provided in the heat dissipation fin in a penetrating manner. The heat dissipation fan is provided on the heat dissipation fin. Tops of the heat absorption ends of the plurality of heat pipes are tightly mounted on a mounting surface of the metal base. The heat pipe arrangement method includes: arranging the heat absorption ends of the plurality of heat pipes in parallel to each other, center distances between the heat absorption ends of the plurality of heat pipes being different.

### CROSS-REFERENCE TO RELATED APPLICATIONS

The application claims priority to Chinese patent application No. 202010982789.0, filed on Sep. 17, 2020, the entire contents of which are incorporated herein by reference.

### FIELD OF TECHNOLOGY

The disclosure relates to the field of heat dissipation of desktop computer CPUs, in particular to a heat pipe arrangement method for a heat dissipation and transfer device.

### BACKGROUND

At present, the relatively new and efficient heat dissipation device is the heat pipe-based heat dissipation device, which usually transfers heat through heat pipes and dissipates heat through the heat dissipation end connected to the other end of the heat pipe. The heat pipe is typically made of a hollow cylindrical slender thin-walled copper pipe, with copper powder attached to the inner wail and sintered at high temperature to form a porous capillary structure. After the heat pipe is tilled with a proper amount of distilled water, both ends of the copper pipe are sealed by sintering under negative pressure (partial vacuum). One end of the heat pipe is the heat absorption end, and the other end is the heat dissipation end. When one end of the heat pipe is heated, the distilled water in the capillary quickly evaporates, and the vapor condenses into water at the heat dissipation end which flows back to the heat absorption end, releasing the latent heat. The distilled water flows back to the heat absorption end along the porous material through the capillary action or gravity, and the cycle repeats, thereby forming a closed recirculation heat transfer and dissipation system.

The heat pipe employs phase transition of a liquid to transfer heat. Within the designed maximum power of the heat pipe, as the heat pipe absorbs more and mote heat, the medium inside can achieve sufficient evaporation and condensation, which makes the heat dissipation efficiency of the heat pipe higher.

As shown in FIG. 1, when the CPU works, the core generates more heat. The surface of the CPU is covered with an isothermalization copper cover, and no isothermalized body can be formed on the isothermalization copper cover, so there exists a temperature gradient distribution centered on the CPU core, that is, a high-temperature region and a low-temperature region on the surface of the CPU.

In the prior art, the heat pipes are arranged in the following forms: four heat pipes 1 are arranged in parallel at equal center distances, as shown in FIG. 2; or four heat pipes 1 are arranged closely and tightly almost without any gap, as shown in FIG. 3. Theoretically, the arrangement forms of FIG. 2 and FIG. 3 are, in principle, both arrangements at equal center distances.

The arrangement forms of heat pipes in the prior art have the following disadvantages: as shown in FIG. 4, the heat pipes are distributed evenly and scattered, and the core region is not completely covered, so that the heat pipes have low heat absorption efficiency and cannot transfer heat efficiently, leading to a poor heat dissipation effect. As shown in FIG. 5, the heat pipes are arranged with no gap, and blank regions at the upper and lower ends are too large, so that heat in the non-core region on the CPU cannot be effectively taken away in time, also leading to a poor heat dissipation effect.

The information disclosed in the Background is only intended to promote the understanding of the overall background of the disclosure, and should not be taken as an admission or in any way implying that the information constitutes the prior art already known to those of ordinary skill in the art.

### SUMMARY

An object of the disclosure is to provide a heat pipe arrangement method for a heat dissipation and transfer device. Heat absorption ends of heat pipes centrally cover the core heat generating region, which increases the heat transfer speed, so that the core heat generating region can be cooler and the heat dissipation speed can be higher when the CPU works.

In order to achieve the above object, the disclosure provides a heat pipe arrangement method for a heat dissipation and transfer device. The heat dissipation and transfer device includes a metal base, a heat dissipation fin, a heat dissipation fan and a plurality of heat pipes. Each of the heat pipes includes a heat absorption end and a heat dissipation end. The heat dissipation ends of the plurality of heat pipes are provided in the heat dissipation fin in a penetrating manner. The heat dissipation fan is provided on the heat dissipation fin. Tops of the heat absorption ends of the plurality of heat pipes are tightly mounted on a mounting surface of the metal base. The heat pipe arrangement method includes: arranging the heat absorption ends of the plurality of heat pipes in parallel to each other, center distances between the heat absorption ends of the plurality of heat pipes being different.

In a preferred embodiment, a shape of the heat pipe includes a U shape and an L shape.

In a preferred embodiment, the number of the plurality of heat pipes is at least four.

In a preferred embodiment, the center distance between the heat absorption ends of the adjacent two heat pipes located in the middle of the plurality of heat pipes is different from the center distance between the heat absorption ends of the adjacent two heat pipes located on a side.

In a preferred embodiment, the center distance between the heat absorption ends of the adjacent two heat pipes located in the middle of the plurality of heat pipes is less than the center distance between the heat absorption ends of the adjacent two heat pipes located on a side.

In a preferred embodiment, the center distance between the heat absorption ends of the adjacent two heat pipes located in the middle of the plurality of heat pipes is greater than the center distance between the heat absorption ends of the adjacent two heat pipes located on a side.

In a preferred embodiment, a bottom of the heat absorption end of each of the heat pipes is a flat surface, and the bottoms of the heat absorption ends of the plurality of heat pipes are in a same plane.

In a preferred embodiment, a bottom of the heat absorption end of each of the heat pipes is a curved surface.

In a preferred embodiment, the heat pipe arrangement method for the heat dissipation and transfer device further includes a copper bottom plate. A mounting surface of the copper bottom plate includes a plurality of grooves, and a shape of a cross section of the plurality of grooves is matched with the curved surface of the bottom of the heat absorption end of the heat pipe.

In a preferred embodiment, a center distance between the plurality of grooves of the copper bottom plate is the same as the center distance between the heat absorption ends of the plurality of heat pipes.

Compared with the prior art, the heat pipe arrangement method for the heat dissipation and transfer device according to the disclosure has the following beneficial effects: the heat pipes fixed to the metal base are arranged at unequal center distances, i.e., the heat pipes are arranged densely in the core heat dissipation region and sparsely in the non-core region. By adjusting the center distances between the heat absorption ends of the heat pipes to be different, the efficiency of the heat pipes in a core heat dissipation region is greatly increased within the designed maximum power of the heat pipes, and the heat pipes in the core heat dissipation region can achieve sufficient evaporation and condensation. This makes the heat dissipation efficiency of the heat pipes in the core heat dissipation region higher, and more heat is taken away; and the heat pipes in the non-core heat dissipation region can effectively absorb heat distributed in other regions on the surface of the CPU copper cover, so that the whole heat dissipation device has a better heat dissipation effect.

### BRIEF DESCRIPTION OF THE DRAWINGS

FIG. 1 is a schematic view showing a heat generating region of a CPU according to the prior art;

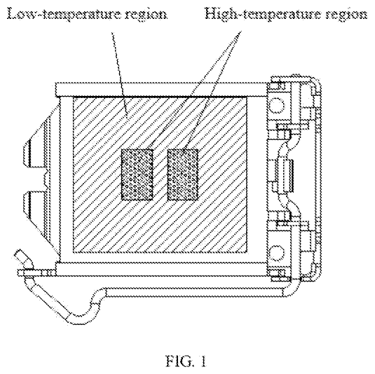

FIG. 2 is a schematic view showing a heat pipe arrangement form according to an embodiment in the prior art;

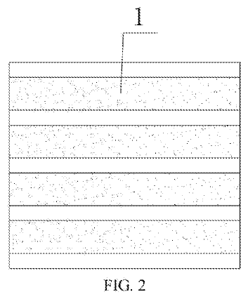

FIG. 3 is a schematic view showing a heat pipe arrangement form according to another embodiment in the prior art;

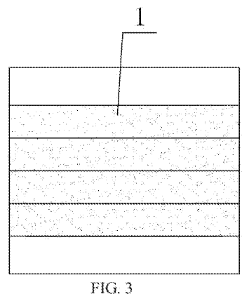

FIG. 4 is a schematic view showing the disadvantage of the heat pipe arrangement form according to an embodiment in the prior art;

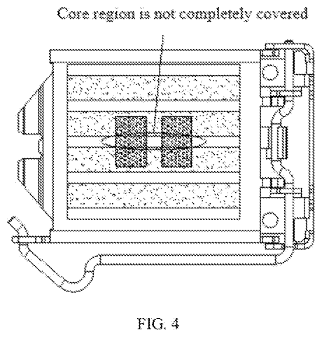

FIG. 5 is a schematic view showing the disadvantage of the heat pipe arrangement form according to another embodiment in the prior art;

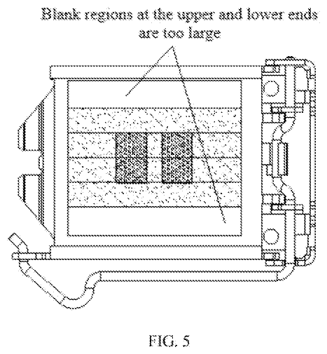

FIG. 6 is a schematic three-dimensional view showing a heat pipe arrangement method for a heat dissipation and transfer device according to an embodiment of the disclosure;

FIG. 7 is a schematic plan view showing a heat pipe arrangement method for a heat dissipation and transfer device according to an embodiment of the disclosure;

FIG. 8 is a schematic view showing the advantage of the heat pipe arrangement method for the heat dissipation and transfer device according to an embodiment of the disclosure;

FIG. 9 is a schematic top view showing the heat pipe arrangement method for the heat dissipation and transfer device according to an embodiment of the disclosure;

FIG. 10 is a schematic front view showing the heat pipe arrangement method for the heat dissipation and transfer device according to an embodiment of the disclosure;

FIG. 11 is a schematic left view showing the heat pipe arrangement method for the heat dissipation and transfer device according to an embodiment of the disclosure; and

FIG. 12 is a schematic view showing the usage status of a heat pipe arrangement method for a heat dissipation and transfer device according to another embodiment of the disclosure.

### DESCRIPTION OF THE EMBODIMENTS

Specific embodiments of the disclosure will be described in detail with reference to the accompanying drawings, but it should be understood that the scope of protection of the disclosure is not limited by the specific embodiments.

Unless otherwise expressly stated, throughout the specification and claims, the term “include” or its variations such as “including” or “included” will be understood as including the stated elements or components, but not excluding other elements or components.

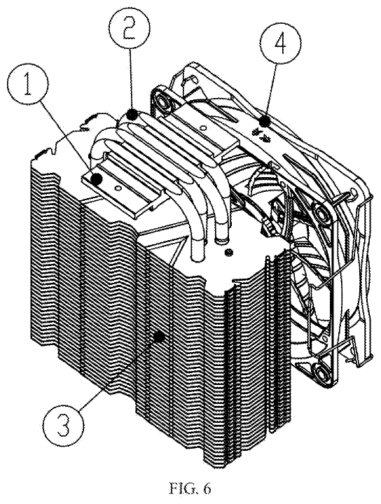

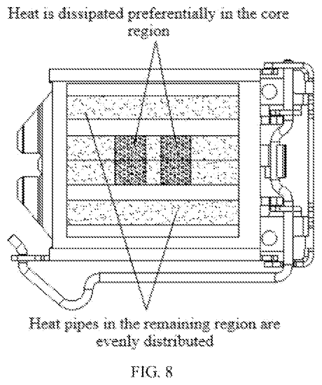

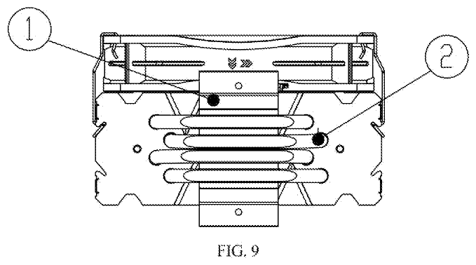

As shown in FIG. 6 to FIG. 9, a preferred embodiment of the disclosure provides a heat pipe arrangement method for a heat dissipation and transfer device. The heat dissipation and transfer device includes a metal base 1, a plurality of heat pipes 2, a heat dissipation fin 3 and a heat dissipation fan 4. Each of the heat pipes includes a heat absorption end and a heat dissipation end. The heat dissipation ends of the plurality of heat pipes 2 are provided in the heat dissipation fin 3 in a penetrating manner. The heat dissipation fan 4 is provided on the heat dissipation fin 3. Tops of the heat absorption ends of the plurality of heat pipes are tightly mounted on a mounting surface of the metal base 1. The heat pipe arrangement method includes: arranging the heat absorption ends of the plurality of heat pipes 2 in parallel to each other, center distances between the heat absorption ends of the plurality of heat pipes 2 being different.

In some embodiments, a shape of the heat pipe 2 includes, but not limited to, a U shape and an L shape. This example takes the U shape as an example.

In some embodiments, the heat absorption ends of the plurality of heat pipes 2 are arranged in parallel to each other and in a same plane, and the center distances between the heat absorption ends of the plurality of heat pipes 2 are different. Each heat pipe 2 is in a U shape. The bottom of the U shape of each of the heat pipes 2 serves as the heat absorption end, and the top serves as the heat dissipation end. The heat absorption ends of the U shapes of the plurality of heat pipes 2 are arranged in parallel to each other and in the same plane.

In some embodiments, the heat absorption ends of the U shapes of the plurality of heat pipes 2 in the same plane are tightly mounted to a heat generating region of a CPU through the metal base 1 by the aid of buckles or screws. Before mounting, a thermal paste is applied to the heat generating region of the CPU. The heat dissipation ends of the U shapes of the plurality of heat pipes 2 are provided in the heat dissipation fin 3 in a penetrating manner. The heat dissipation fan 4 is provided on the heat dissipation fin 3.

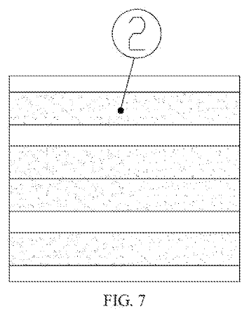

Referring to FIG. 7 to FIG. 9, in some embodiments, the number of the plurality of heat pipes 2 is at least four. The center distance h between the adjacent two heat pipes 2 located in the middle of the plurality of heat pipes 2 is different from the center distance H between the adjacent two heat pipes 2 located on a side. Preferably, h is less than H.

In some embodiments, the number of the plurality of heat pipes 2 may also be more than four, for example, five, six, seven, eight, etc. If the number is five, the heat absorption ends between the three heat pipes in the middle may be arranged tightly or closer, and the heat absorption ends of the two heat pipes on the side may be arranged slightly farther apart. If the number is six, the two heat pipes in the middle may be arranged tightly or closest, the two heat pipes on the outer side may be arranged slightly farther apart, and the outermost two heat pipes are arranged at the largest distance. In the case of the number is seven, eight or more, the arrangement form may be analogized, i.e., the heat pipes in the middle have the largest density and the outermost heat pipes have the smallest density. In general cases, the arrangement of the heat pipes 2 at unequal distances in this example is only applicable to the case where the heat generating region is concentrated in the middle position of the CPU, but the disclosure is not limited thereto. If the heat generating regions are concentrated on the two sides of the CPU, then the heat pipes 2 are arranged more densely in the area where the heat generating regions are concentrated. The heat-conducting medium in the heat pipe 2 is characterized by the fact that the higher the temperature, the higher the thermal conductivity. Therefore, the larger arrangement density of the heat pipes 2 in the area where the heat generating regions are concentrated is beneficial to the improvement of the heat dissipation efficiency.

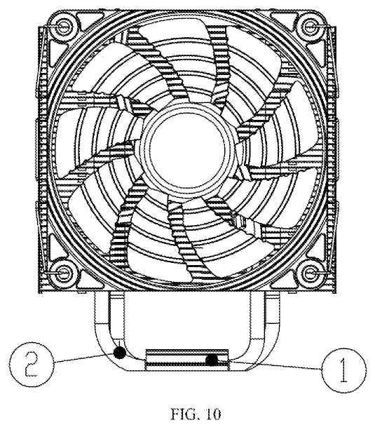

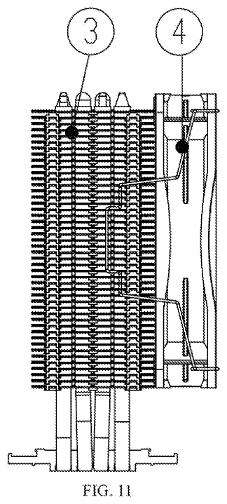

As shown in FIG. 10 to FIG. 11, in some embodiments, the heat dissipation ends of the U shapes of the plurality of heat pipes 2 provided in the heat dissipation fin 3 in the penetrating manner are arranged not in parallel, but in a staggered manner, which is more beneficial to the uniform heat conduction between the heat pipes 2 and the heat dissipation fin 3.

Still referring to FIG. 6, in some embodiments, a bottom, of each of the heat pipes 2 in this example is a flat surface, and the bottoms of the plurality of heat pipes 2 are in a same plane, which is used to be mounted tightly to the heat generating region of the CPU.

In some embodiments, the mounting surface of the metal base 1 may be a flat surface or be provided with a plurality of grooves. When the mounting surface of the metal base 1 is a flat surface, then a top of each heat pipe 2 should also be a flat surface, and the flat surfaces of the tops of the plurality of heat pipes 2 should be on a same plane. When the mounting surface of the metal base 1 is provided with a plurality of grooves, the top of the heat pipe 2 should be a curved surface, and the plurality of grooves on the mounting surface of the metal base 1 need to be matched with the curved surfaces of the tops of the plurality of heat pipes 2.

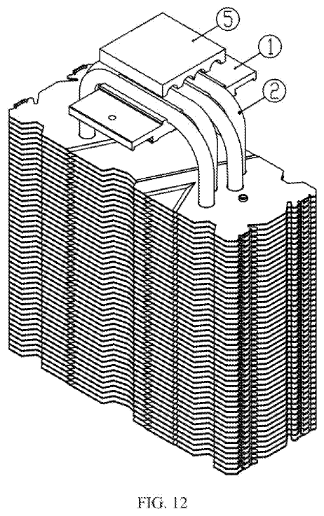

As shown in FIG. 12, FIG. 12 is a schematic view showing a heat pipe arrangement method for a heat dissipation and transfer device according to another embodiment of the disclosure. This embodiment is different from the aforementioned embodiment in that: in the aforementioned embodiment, the heat absorption ends of the heat pipes 2 are slightly flattened (that is, the top of each heat pipe 2 is a fiat surface), so that the flat surfaces of the tops of the heat absorption ends of the plurality of heat pipes 2 are on the same plane, the bottoms of the heat absorption ends of the plurality of heat pipes 2 are on a same plane, and the two planes are parallel to each other. The tops of the heat absorption ends of the plurality of heat pipes 2 are tightly mounted to the metal base 1, and the bottoms are tightly mounted to the heat generating region of the CPU. In the embodiment of FIG. 7, the heat absorption ends of the heat pipe 2 are not flattened, but the metal base 1 is provided with the grooves at center distances the same as those between the heat absorption ends of the plurality of heat pipes 2 (or provided with a whole groove capable of containing the heat absorption ends of the plurality of heat pipes 2 at the same time), so as to be tightly mounted to the tops of the heat absorption ends of the plurality of heat pipes 2. Besides, a copper bottom plate 5 is additionally provided. The copper bottom plate is provided with grooves the same as those on the metal base 1, so as to be tightly mounted to the bottoms of the heat absorption ends of the plurality of heat pipes 2. That is, the grooved surfaces of the metal base 1 and the copper bottom plate 5 are locked with each other, and holes capable of containing the plurality of heat absorption ends are formed in the middle to install the plurality of heat absorption ends. During mounting, the gap between the heat absorption end and the groove is filled with a thermal paste or solder, such that the grooves on the metal base 1 and the copper bottom plate 5 are integrated with the heat absorption end. The surface of the copper bottom plate 5 opposite to the grooves is a flat surface, which is used to be tightly mounted to the heat generating region of the CPU.

Based on the above, the heat pipe arrangement method for the heat dissipation and transfer device according to the disclosure has the following advantages: the heat pipes fixed to the metal base are arranged at unequal center distances, i.e., the heat pipes are arranged densely in the core heat dissipation region and sparsely in the non-core region. By adjusting the center distances between the heat absorption ends of the heat pipes to be different, the efficiency of the heat pipes in a core heat dissipation region is greatly increased within the designed maximum power of the heat pipes, and the heat pipes in the core heat dissipation region can achieve sufficient evaporation and condensation. This makes the heat dissipation efficiency of the heat pipes in the core heat dissipation region higher, and more heat is taken away; and the heat pipes in the non-core heat dissipation region can effectively absorb heat distributed in other regions on the surface of the CPU copper cover, so that the whole heat dissipation device has a better heat dissipation effect.

The foregoing descriptions of specific exemplary implementations of the disclosure are for the purpose of illustration and exemplification. These descriptions are not intended to limit the disclosure to the precise form disclosed, and it is apparent that many changes and variations can be made in light of the above teachings. The exemplary embodiments are selected and described for the purpose of explaining specific principles of the disclosure and practical application thereof, so that those skilled in the art can realize and utilize various exemplary implementations and various alternatives and variations of the disclosure. The scope of the disclosure is intended to be defined by the claims and their equivalents.

What is claimed is:

1. A heat pipe arrangement method the a heat dissipation and transfer device, the heat dissipation and transfer device comprising a metal base, a heat dissipation fin, a heat dissipation fan and a plurality of heat pipes, each of the heat pipes comprising a heat absorption end and a heat dissipation end, the heat dissipation ends of the plurality of heat pipes being provided in the heat dissipation fin in a penetrating manner, the heat dissipation fan being provided on the heat dissipation fin, and tops of the heat absorption ends of the plurality of heat pipes being tightly mounted on a mounting surface of the metal base, wherein the heat pipe arrangement method comprises; arranging the heat absorption ends of the plurality of heat pipes in parallel to each other, center distances between the heat absorption ends of the plurality of heat pipes being different.

2. The heat pipe arrangement method for the heat dissipation and transfer device according to claim 1, wherein a shape of the heat pipe comprises a U shape and an L shape.

3. The heat pipe arrangement method for the heat dissipation and transfer device according to claim 2, wherein the number of the plurality of heat pipes is at least four.

4. The heat pipe arrangement method for the heat dissipation and transfer device according to claim 1, wherein the center distance between the heat absorption ends of the adjacent two heat pipes located in the middle of the plurality of heat pipes is different from the center distance between the heat absorption ends of the adjacent two heat pipes located on a side.

5. The heat pipe arrangement method for the heat dissipation and transfer device according to claim 1, wherein the center distance between the heat absorption ends of the adjacent two heat pipes located in the middle of the plurality of heat pipes is less than the center distance between the heat absorption ends of the adjacent two heat pipes located on a side.

6. The heat pipe arrangement method for the heat dissipation and transfer device according to claim 1, wherein the center distance between the heat absorption ends of the adjacent two heat pipes located in the middle of the plurality of heat pipes is greater than the center distance between the heat absorption ends of the adjacent two heat pipes located on a side.

7. The heat pipe arrangement method for the heat dissipation and transfer device according to claim 1, wherein a bottom of the heat absorption end of each of the heat pipes is a flat surface, and the bottoms of the heat absorption ends of the plurality of heat pipes are in a same plane.

8. The heat pipe arrangement method for the heat dissipation and transfer device according to claim 1, wherein a bottom of the heat absorption end of each of the heat pipes is a curved surface.

9. The heat pipe arrangement method for the heat dissipation and transfer device according to claim 8, further comprising a copper bottom plate, wherein a mounting surface of the copper bottom plate comprises a plurality of grooves, and a shape of a cross section of the plurality of grooves is matched with the curved surface of the bottom of the heat absorption end of the heat pipe.

10. The heat pipe arrangement method for the heat dissipation and transfer device according to claim 8, wherein a center distance between the plurality of grooves of the copper bottom plate is the same as the center distance between the heat absorption ends of the plurality of heat pipes.
